(19) United States
(12) Patent Application Publication
(10) Pub. No.: US 2022/0122856 A1
(43) Pub. Date: Apr. 21, 2022

(54) DIFFUSION FURNACE

(71) Applicant: CHANGXIN MEMORY TECHNOLOGIES, INC., Hefei City (CN)

(72) Inventor: Zheng CUI, Hefei (CN)

(21) Appl. No.: 17/401,400

(22) Filed: Aug. 13, 2021

Related U.S. Application Data
(63) Continuation of application No. PCT/CN2021/100204, filed on Jun. 15, 2021.

(30) Foreign Application Priority Data
Oct. 15, 2020 (CN) 202011101475.1

(51) Int. Cl. H01L 21/67

(52) U.S. Cl. CPC H01L 21/67109

(57) ABSTRACT

Provided is a diffusion furnace, including a reaction chamber extending in a first direction and a plurality of gas channels. The reaction chamber has an exhaust end; a plurality of wafers are disposed one after the other in the first direction; the surfaces of the wafers extend in a second direction; and the second direction is perpendicular to the first direction or is at an acute angle to the first direction. The plurality of gas channels pass through the side wall of the reaction chamber to introduce external reaction gas into the reaction chamber. The gas channels are distributed in the first direction from the exhaust end. The axis of each gas channel is at an acute angle to the second direction.

### CROSS-REFERENCE TO RELATED APPLICATION

This is a continuation application of International Patent Application No. PCT/CN2021/100204, filed on Jun. 15, 2021, which claims priority to Chinese Patent Application No. 202011101475.1, filed on Oct. 15, 2020 and entitled “Diffusion Furnace”. The entire contents of International Patent Application No. PCT/CN2021/100204 and Chinese Patent Application No. 202011101475.1 are incorporated herein by reference in their entireties.

### TECHNICAL FIELD

The present application relates to the field of semiconductor manufacturing, in particular, a diffusion furnace.

### BACKGROUND

A diffusion furnace is one of the important process devices in a pre-process of a semiconductor production line, and is used in the processes (such as diffusion, oxidation, annealing, alloying, and sintering) in the large-scale integrated circuit industry, the discrete device industry, the photoelectric device industry, the optoelectronic device industry, the optical fiber industry and other industries.

In the related art, when a deposition process is performed on a plurality of wafers through a diffusion furnace, the amount of reaction gas in contact with wafer is different for the different wafers, so that thickness of a film deposited on the wafer is different for different wafers, and the uniformity of a product is poor. Furthermore, since the reaction gas is diffused from an edge to the center of each wafer, the film thickness at the surface edge of the wafer is greater than the film thickness at the surface center of the wafer, that is, the thickness of the film deposited on the surface of the wafer is not uniform, resulting in a decrease in product yield.

### SUMMARY

The embodiments of the present application provide a diffusion furnace, including a reaction chamber extending in a first direction and a plurality of gas channels. The reaction chamber has an exhaust end. A plurality of wafers may be disposed one after the other in the first direction. Surfaces of the wafers extend in a second direction. The second direction is perpendicular to the first direction or the second direction is at an acute angle to the first direction. The plurality of gas channels pass through the side wall of the reaction chamber to introduce external reaction gas into the reaction chamber. The gas channels are distributed in the first direction from the exhaust end. The axis of each gas channel is at an acute angle to the second direction.

### BRIEF DESCRIPTION OF THE DRAWINGS

FIG. 1 is a schematic view of a diffusion furnace in the related art;

FIG. 2 is a schematic view of a diffusion furnace of a first embodiment of the present application;

FIG. 3 is a schematic view illustrating that gas channels of the diffusion furnace of the first embodiment of the present application pass through the side wall of a reaction chamber;

FIG. 4 is a schematic view of distribution of gas channels on the side wall of a reaction chamber of the diffusion furnace of the first embodiment of the present application;

FIG. 5 is a schematic view of distribution of gas channels on the side wall of a reaction chamber of the diffusion furnace of a second embodiment of the present application;

FIG. 6 is a schematic view of distribution of gas channels on the side wall of a reaction chamber of the diffusion furnace of a third embodiment of the present application;

FIG. 7 is a schematic view of distribution of gas channels on the side wall of a reaction chamber of the diffusion furnace of a fourth embodiment of the present application; and

FIG. 8 is a schematic view illustrating that gas channels of the diffusion furnace of a fifth embodiment of the present application pass through the side wall of a reaction chamber.

### DETAILED DESCRIPTION

Specific implementations of a diffusion furnace provided by the embodiments of the present application are described in detail below in combination with the accompanying drawings.

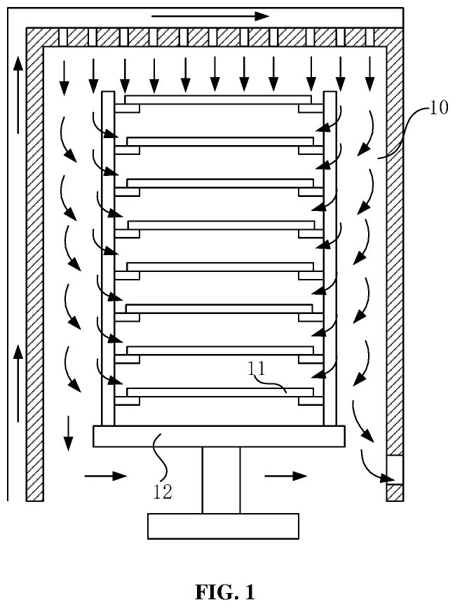

FIG. 1 is a schematic view of a diffusion furnace in the related art. Referring to FIG. 1, the diffusion furnace has a reaction chamber 10. A wafer 11 is placed on a wafer boat 12 and located in the reaction chamber 10. During the deposition process, reaction gas is sprayed from the top of the reaction chamber 10, and is diffused to the surface of the wafer 11 (a diffusion path of the reaction gas is indicated by the arrow in FIG. 1) for deposition. In the related art, the diffusion furnace has the defects caused by the fact that the reaction gas is sprayed from the top of the reaction chamber 10. In the deposition process, the reaction gas is perpendicularly sprayed relative to the wafer 11, so that the wafer 11 at the top is in contact with more reaction gas, and the wafer 11 at the bottom is in contact with less reaction gas as it is sheltered. In this case, film thicknesses of the same batch of wafers 11 are different, and the product uniformity is poor. For the sheltered wafer 11 at the bottom, the reaction gas is diffused from the edge of the wafer 11 to the center of the wafer 11, and thus the film thickness at the edge of the surface of the wafer 11 to is greater than the film thickness at the center of the surface of the wafer, which results in non-uniform film thickness on the surface of the wafer 11 and a decrease in product yield.

Therefore, it is intended to improve the uniformity of a film layer deposited on the surface of the wafer 1 at the present.

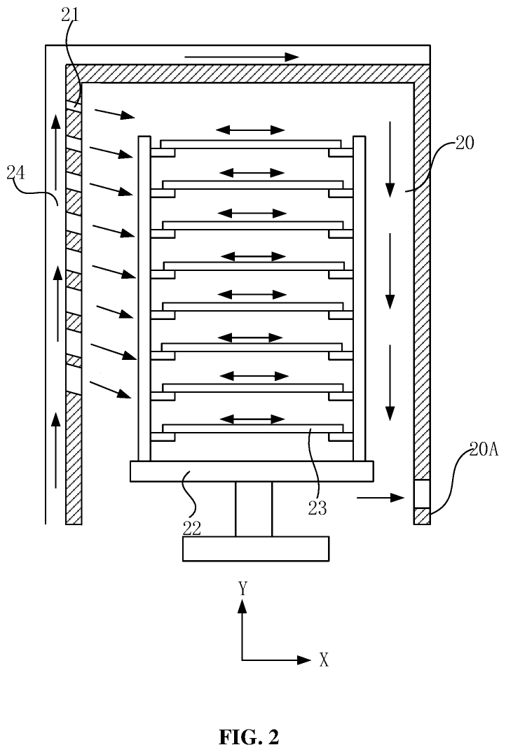

FIG. 2 is a schematic view of a diffusion furnace of a first embodiment of the present application. Referring to FIG. 2, the diffusion furnace includes a reaction chamber 20 and a plurality of gas channels 21.

The reaction chamber 20 is a chamber for reaction. A wafer 23 may be placed in the reaction chamber 20 for film layer deposition and other processes. In some embodiments, the diffusion furnace further includes a wafer boat 22. The wafer boat 22 may be positioned in the reaction chamber 20 and carry the wafer 23 to place the wafer 23 into the reaction chamber 20. The wafer boat 22 is rotatable to drive the wafer 23 to rotate in the reaction chamber 20, to allow the uniform deposition of the reaction gas.

The reaction chamber 20 extends in a first direction. As shown in FIG. 2, the reaction chamber 20 extends in a Y direction. During processing, a plurality of wafers 23 are disposed one after the other in the first direction in the reaction chamber 20, and the surfaces of the wafers 23 extend in a second direction. The second direction is perpendicular to the first direction or is at an acute angle to the first direction. In the first embodiment, the first direction is the Y direction, and the second direction is an X direction. The first direction is perpendicular to the second direction. In other embodiments of the present application, the second direction is at an acute angle to the first direction.

The reaction chamber 20 has an exhaust end 20A. The exhaust end 20A is configured to exhaust waste gas in the reaction chamber 20. In the present embodiment, the exhaust end 20A is provided at the bottom of the reaction chamber 20. In other embodiments of the present application, the exhaust end 20A may also be provided at the top or in the middle of the reaction chamber 20.

The gas channels 21 pass through the side wall of the reaction chamber 20 to introduce external reaction gas into the reaction chamber 20. The gas channels 21 pass through the side wall of the reaction chamber 20 from the exterior of the reaction chamber 20 to communicate the exterior with the reaction chamber 20, so that the reaction gas can be fed into the reaction chamber 20.

In some embodiments, the diffusion furnace further includes a gas inlet conduit 24. The gas inlet conduit 24 is in communication with the gas channels 21. The reaction gas is conveyed to the gas channels 21 through the gas inlet conduit 24. In the present embodiment, the gas inlet conduit 24 is a primary conduit. All the gas channels 21 are in communication with the gas inlet conduit 24. In other embodiments of the present application, the gas inlet conduit 24 includes a plurality of pipelines. Each pipeline may be in communication with one or more gas channels 21 to respectively convey the reaction gas to the gas channels 21, to realize the group control of the gas channels 21.

In some embodiments, the gas inlet end of the gas inlet conduit 24 and the exhaust end 20A of the reaction chamber 20 are located on the same side of the diffusion furnace. For example, both the gas inlet end and the exhaust end are located at the bottom of the reaction chamber 20. In other embodiments of the present application, the gas inlet end of the gas inlet conduit 24 and the exhaust end 20A of the reaction chamber 20 are located on different sides. For example, the gas inlet end of the gas inlet conduit 24 is located at the top end of the reaction chamber 20, and the exhaust end 20A is located at the bottom end of the reaction chamber 20, or the gas inlet end of the gas inlet conduit 24 is located at the bottom end of the reaction chamber 20, and the exhaust end 20A is located at the top end of the reaction chamber 20. The present application is not limited thereto.

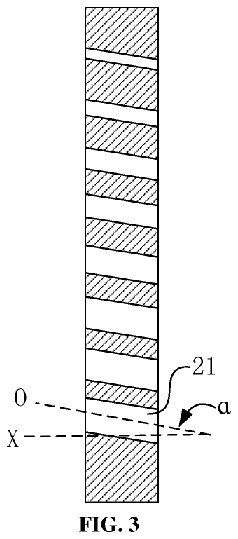

The gas channels 21 are distributed in the first direction from the exhaust end 20A, and the axis of each gas channel 21 is at an acute angle to the second direction. For example, FIG. 3 is a schematic view illustrating that gas channels of the first embodiment of the disclosure pass through the side wall of a reaction chamber. The axis O of the gas channel 21 is not parallel to the second direction (X direction), but is at an acute angle α to the second direction, which enable the reaction gas sprayed from the gas channel 21 to directly reach the center of the wafer 23, thereby solving the problem in the deposition process that the film layer is thick at the edge region of the wafer and is thin at the center region of the wafer. Due to the exhausting action of the exhaust end 20A, the reaction gas will be diffused towards the edge region after reaching the center of the wafer 23, and the wafer boat 22 rotates to accelerate the diffusion of the gas, so that the thickness of the deposited film layer is more uniform at the center region and the edge region of the surface of the single wafer 23.

In some embodiments, the acute angle α ranges from 3 degrees to 20 degrees. If the angle is too small, the reaction gas will be sprayed out in a direction parallel to the wafer 23. If the angle is too large, the reaction gas will be sprayed to the edge of the wafer 23 and cannot reach the center region of the surface of the wafer 23. In one example, the acute angle α is 15 degrees.

In some embodiments, a projection of the gas channel 21 in the second direction (X direction) is located between two adjacent wafers 23 to alleviate the blockage effect of the side surfaces of the wafers 23 to the conveyance of the reaction gas.

In some implementations, diameters of the gas channels 21 successively decrease in the first direction from the exhaust end 20A. For example, as shown in FIG. 2 and FIG. 3, the gas channels 21 are distributed in the Y direction from the exhaust end 20A, and the diameters of the gas channels 21 successively decrease. That is, the closer to the exhaust end 20A, the larger the diameter of the gas channel 21.

Since waste gas in the reaction chamber 20 is discharged from the exhaust end 20A, when the waste gas is discharged, a part of the reaction gas will be discharged with the waste gas. The concentration of the reaction gas in a region adjacent to the exhaust end 20A is decreased, thereby resulting in low uniformity of the same batch of wafers 23. Therefore, by means of the above design of the diameters of the gas channels 21, the diffusion furnace of the embodiments of the present application compensates the region with low reaction gas concentration. As such, a flow rate of the reaction gas in the region adjacent to the exhaust end 20A is higher, so as to increase the concentration of the reaction gas in the region to improve the uniformity of the same batch of wafers 23 and increase the product yield.

In addition, compared with the related art where the gas channels 21 are formed at the top, the diffusion furnace of the embodiments of the present application where the gas channels 21 are formed in the side wall of the reaction chamber 20 can reduce the difference in reaction gas concentration at the different wafers 23 caused by the mutual blockage of the wafers 23, thereby reducing the occurrences of non-uniform thicknesses of film layers deposited on the same batch of wafers 23.

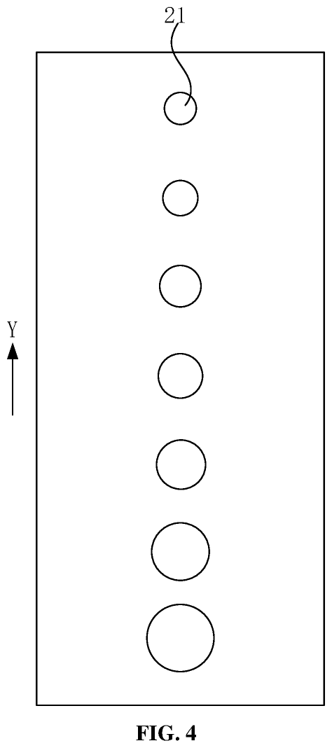

In some implementations, FIG. 4 is a schematic view of distribution of gas channels of the first embodiment of the present application on the side wall of a reaction chamber. Referring to FIG. 4, a plurality of gas channels 21 are distributed one after the other in the first direction (Y direction) from the exhaust end 20A, and the diameters of the gas channels 21 successively decrease by a preset value. The preset value may be determined according to a difference between concentration of reaction gas at the exhaust end 20A of the reaction chamber 20 and concentration of reaction gas at other regions. The preset value may be a constant value, and the preset numerical value may also be a variable value. For example, the preset value may be gradually decreased in a progressively decreasing manner.

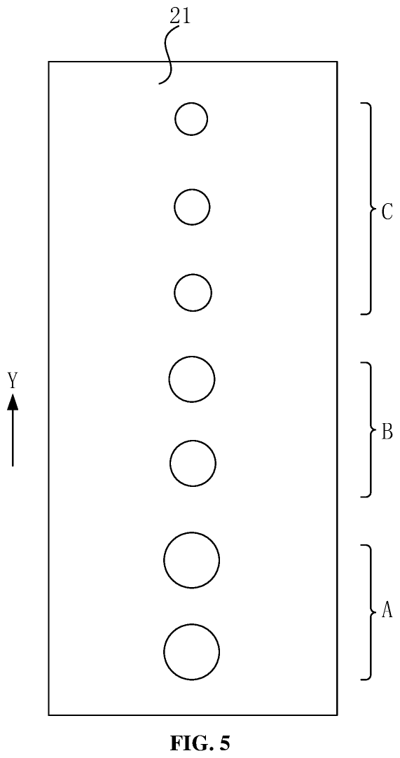

In the first embodiment of the present application, the diameters of the gas channels 21 successively decrease. In other embodiments of the present application, the gas channels 21 are divided into a plurality of channel groups in the first direction. The diameters of the gas channels 21 in the same channel group are equal to each other. For example, FIG. 5 is a schematic view of distribution of gas channels of a second embodiment of the present application on the side wall of a reaction chamber. The difference from the first embodiment is that the gas channels 21 are divided into a plurality of channel groups in the first direction (Y direction). FIG. 5 schematically illustrates channel groups A, B, and C. The diameters of the gas channels 21 in the same channel group are equal to each other, and the diameters of the gas channels 21 in different channel groups are different. The closer the channel group is to the exhaust end 20A, the larger the diameter of the gas channels 21 in the channel groups.

If there are large amounts of the gas channels 21, the concentration of the reaction gas in the regions of the reaction chamber 20 corresponding to several adjacent gas channels 21 may be affected by the exhausting of the exhaust end 20A to the same degree. The gases inputted by different gas channels 21 have different flow rates, which will cause a phenomenon that the reaction gas concentration is different in different regions of the reaction chamber. Therefore, in order to relieve this phenomenon, said several gas channels 21 may be classified into the same channel group. The diameters of the several gas channels 21 are equal to each other to make the gas concentration in the reaction chamber 20 uniform.

In some implementations, the present application also provides a third embodiment. In the third embodiment, each gas channel 21 is composed of at least one sub-channel 21A. The sub-channel 21A passes through the side wall of the reaction chamber 20. In one example a plurality of the sub-channels 21A are arranged one after the other on the side wall of the reaction chamber 20 in a second direction. The second direction is perpendicular to the first direction or is at an acute angle to the first direction.

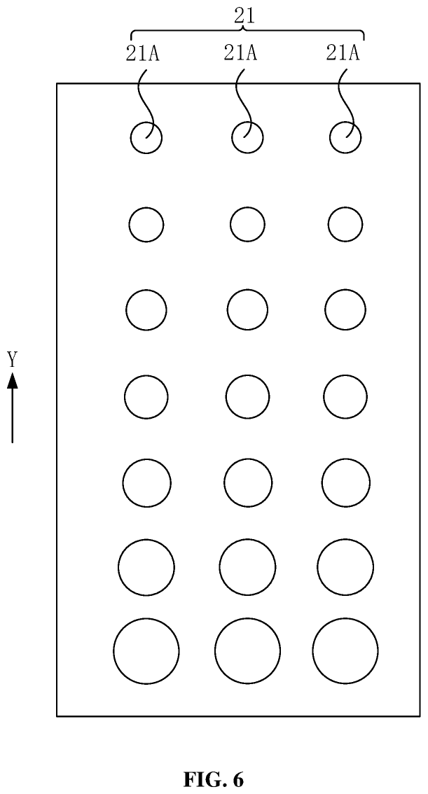

In one example, referring to FIG. 6, it is a schematic view of distribution of gas channels of a third embodiment of the present application on the side wall of a reaction chamber. In order to increase an action region of the gas channels 21, each gas channel 21 is composed of a plurality of sub-channels 21A. In the present embodiment, each gas channel 21 is composed of three sub-channels 21A. In other embodiments of the present application, the number of the sub-channels 21A may be selected according to actual needs. For example, the number of the sub-channels 21A may be selected according to a width of the action region of the reaction gas. If the action region of the reaction gas is required to be wide, the number of the sub-channels 21A may be increased. If the action region of the reaction gas is required to be narrow, the number of the sub-channels 21A may be decreased.

The sub-channel 21A passes through the side wall of the reaction chamber 20, and the sub-channels 21A are not in communication with each other. The sub-channels 21A are arranged one after the other on the side wall of the reaction chamber 20 in the second direction. As shown in FIG. 6, the second direction is the X direction. The second direction is perpendicular to the first direction or is at an acute angle to the first direction. In the present embodiment, the first direction is the Y direction, and the second direction is the X direction. The two directions are perpendicular to each other. In other embodiments of the present application, the second direction is at an acute angle to the first direction.

In other embodiments of the present application, also referring to the second embodiment, the gas channels 21 are divided into a plurality of channel groups. The diameters of the sub-channels 21A in the same channel group are equal to each other.

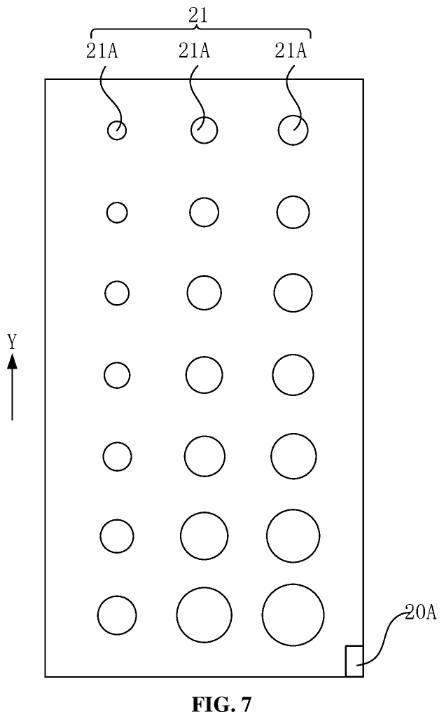

In the third embodiment, the diameters of the sub-channels 21A of the same gas channel 21 are equal to each other. In other embodiments of the present application, the diameters of the sub-channels 21A of the same gas channel 21 successively increase according to distances to the exhaust end 20A from far to near. That is, the diameters of the sub-channels of the same gas channel successively increase in a direction towards the exhaust end. For example, referring to FIG. 7, it is a schematic view of distribution of gas channels of a fourth embodiment of the present application on the side wall of a reaction chamber. In the present embodiment, the exhaust end 20A is located on the side where the bottom of the reaction chamber 20 is located. Regions of different sub-channels 21A have different distance to the exhaust end 20A, which also causes these regions to be affected by the exhausting of the exhaust end 20A to different degrees. Therefore, the diameters of the sub-channels 21A of the same gas channel 21 increase successively according to the distances to the exhaust end 20A from far to near, that is, the closer to the exhaust end 20A, the larger the diameters of the sub-channels 21A (i.e. the diameters of the sub-channels of the same gas channel successively increase in a direction towards the exhaust end), so as to balance the influence of the exhausting of the exhaust end 20A on the reaction gas concentration.

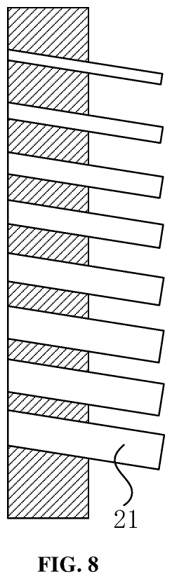

In all the above-mentioned embodiments, the gas channels 21 only pass through the side wall of the reaction chamber 20. In other embodiments of the present application, the gas channels 21 protrude from the side wall of the reaction chamber 20. For example, referring to FIG. 8, it is a schematic view illustrating that gas channels of the diffusion furnace of a fifth embodiment of the present application pass through the side wall of a reaction chamber. In the present embodiment, the gas channel 21 protrudes from the side wall of the reaction chamber 20. That is, the gas channel 21 extends into the interior the reaction chamber 20, so that the reaction gas can be sprayed to the center region of the surface of the wafer 23. In some implementations, the uniformity of the thickness of a film layer deposited on the surface of a single wafer 23 is improved.

In some implementations, the length of a portion of the gas channel 21 protruding beyond the side wall of the reaction chamber 20 is 1 to 5 mm. If the length of the portion of the gas channel 21 protruding beyond the side wall of the reaction chamber 20 is too large, the gas channel may affect the movement of the wafer 23 in the reaction chamber 20.

The diffusion furnace of the present application can improve the problem of a non-uniform thickness of a film layer deposited on the surface of a single wafer 23, and can also improve the influence of the exhausting of the exhaust end 20A on the concentration of the reaction gas in the reaction chamber 20, so that the stability of the same batch of wafers 23 is greatly improved, and the product yield is increased.

The above descriptions are only the preferred implementations of the present application. It should be noted that those of ordinary skill in the art can further make several improvements and retouches without departing from the principles of the present application. These improvements and retouches shall also all fall within the protection scope of the present application.

1. A diffusion furnace, comprising:
a reaction chamber extending in a first direction, wherein the reaction chamber has an exhaust end; a plurality of wafers are disposed one after the other in the first direction; surfaces of the wafers extend in a second direction; the second direction is perpendicular to the first direction, or the second direction is at an acute angle to the first direction; and
a plurality of gas channels passing through a side wall of the reaction chamber to introduce external reaction gas into the reaction chamber, wherein the gas channels are distributed in the first direction from the exhaust end, and an axis of each gas channel is at an acute angle to the second direction.

2. The diffusion furnace of claim 1, wherein the acute angle ranges from 3 degrees to 20 degrees.

3. The diffusion furnace of claim 1, wherein diameters of the gas channels successively decrease in the first direction from the exhaust end.

4. The diffusion furnace of claim 3, wherein each gas channel is composed of at least one sub-channel passing through the side wall of the reaction chamber.

5. The diffusion furnace of claim 4, wherein a plurality of the sub-channels are arranged one after the other on the side wall of the reaction chamber in the second direction.

6. The diffusion furnace of claim 5, wherein diameters of the sub-channels of the same gas channel are equal to each other.

7. The diffusion furnace of claim 5, wherein diameters of the sub-channels of the same gas channel successively increase in a direction towards the exhaust end.

8. The diffusion furnace of claim 3, wherein the gas channels are divided into a plurality of channel groups in the first direction, and the diameters of the gas channels in the same channel group are equal to each other.

9. The diffusion furnace of claim 3, wherein the diameters of the gas channels successively decrease by a preset value.

10. The diffusion furnace of claim 1, wherein a projection of a gas outlet of each of the gas channels in the second direction is located between two adjacent wafers.

11. The diffusion furnace of claim 1, wherein the gas channels protrude beyond the side wall of the reaction chamber.

12. The diffusion furnace of claim 11, wherein a length of a portion of each gas channel protruding beyond the side wall of the reaction chamber is 1 to 5 mm.

13. The diffusion furnace of claim 1, wherein the diffusion furnace further comprises a wafer boat for carrying a wafer in the reaction chamber; and the wafer boat is rotatable to drive the wafer to rotate.

14. The diffusion furnace of claim 1, wherein the diffusion furnace further comprises a gas inlet conduit; and the gas inlet conduit is in communication with the gas channels to convey reaction gas to the gas channels.

15. The diffusion furnace of claim 14, wherein a gas inlet end of the gas inlet conduit and the exhaust end of the reaction chamber are located on the same side of the diffusion furnace.
